(19) United States
(12) Patent Application Publication
(10) Pub. No.: US 2024/0222495 A1
(43) Pub. Date: Jul. 4, 2024

(54) VERTICAL FIELD-EFFECT TRANSISTOR STRUCTURE AND METHOD FOR PRODUCING A VERTICAL FIELD-EFFECT TRANSISTOR STRUCTURE

(71) Applicant: Robert Bosch GmbH, Stuttgart (DE)

(72) Inventor: Daniel Krebs, Aufhausen (DE)

(21) Appl. No.: 18/394,347

(22) Filed: Dec. 22, 2023

(30) Foreign Application Priority Data
Jan. 3, 2023 (DE) 10 2023 200 039.3

(51) Int. Cl. H01L 29/78; H01L 29/423; H01L 29/66

(52) U.S. Cl. CPC H01L 29/7813; H01L 29/4236; H01L 29/66734

(57) ABSTRACT

A vertical field-effect transistor structure including a semiconductor body having a drift zone having a first doping of a first doping type, multiple first trenches, and multiple second trenches. The first trenches have at most a first trench depth, and the second trenches have at least a second trench depth. The second trench depth is at least 50 nm longer than the first trench depth. The structure includes a shielding region adjacent to each trench bottom of the first trenches, which has a second doping of a second doping type, and at least one gate electrode in each of the first and second trenches, which is electrically insulated at least from the adjacent trench bottom and trench side wall. Each region adjacent to the trench bottoms of the second trenches has exclusively the first doping of the drift zone and is free from the second doping.

### FIELD

The present invention relates to a vertical field-effect transistor structure. The present invention also relates to a method for producing a vertical field-effect transistor structure.

### BACKGROUND INFORMATION

German Patent No. DE 102 24 201 A1 describes a semiconductor component having a breakthrough current path, which semiconductor component comprises a semiconductor body having a source zone lying on a surface of the semiconductor body, a channel zone adjacent to the source zone, and an n-doped drift zone adjacent to the channel zone. Multiple trenches extend from the surface of the semiconductor body into the drift zone, wherein a p-doped shielding region is adjacent to each trench bottom of the trenches. In each of the trenches, two gate electrodes and one electrode extending from the surface of the semiconductor body between the two gate electrodes to the shielding region adjacent to the trench bottom are formed, wherein the gate electrodes are electrically insulated from the adjacent trench bottom, an adjacent trench side wall and the adjacent electrodes of the relevant trench by means of an insulation layer.

### SUMMARY

The present invention provides a vertical field-effect transistor structure and a method for producing a vertical field-effect transistor structure.

The present invention provides vertical field-effect transistor structures in which a JFET forms between the shielding regions of a vertical field-effect transistor structure according to the present invention, which JFET limits a current through the channel zone of the vertical field-effect transistor structure in the event of a short circuit. Due to the different trench depths of the first and second trenches of the vertical field-effect transistor structure according to the present invention and the formation of its shielding regions exclusively adjacent to each trench bottom of the first trenches (i.e., an “absence” of shielding regions on each trench bottom of the second trenches), the vertical field-effect transistor structure according to the present invention is also less sensitive to process variations/process variabilities. While, in the related art, an insufficient limitation of the short-circuit current often already results when a target intermediate distance between two adjacent shielding regions is exceeded by only 10 nm (nanometers), this disadvantage is remedied in the vertical field-effect transistor structure according to the present invention. During production of the vertical field-effect transistor structure according to the present invention, it is likewise no longer a concern that, if the target distance is not met, a complete short circuit of the JFET results and thus a current flow is prevented, and the switch-on resistance goes to infinity.

By means of the different trench depths of the first and second trenches of the vertical field-effect transistor structure according to the present invention and the formation of their shielding regions exclusively adjacent to each trench bottom of the first trenches, a less precise adherence to an intermediate distance between two adjacent shielding regions is thus possible. This facilitates production of the vertical field-effect transistor structure according to the present invention while maintaining the advantageous limitation of the short-circuit current and thus also helps to reduce its production costs. The present invention thus also increases the possible applications for vertical field-effect transistor structures.

In an advantageous embodiment of the vertical field-effect transistor structure of the present invention, a first average dielectric thickness oriented perpendicularly to the surface of the semiconductor body can be defined for the at least one insulation dielectric covering at least part of the area of all the trench bottoms of the first trenches, and a second average dielectric thickness oriented perpendicularly to the surface of the semiconductor body can be defined for the at least one insulation dielectric covering at least part of the area of all the trench bottoms of the second trenches, wherein the second average dielectric thickness is greater than the first average dielectric thickness at least by a factor of 1.2. In this way, an effect limiting the short-circuit current between each shielding region adjacent to the trench bottoms of the first trenches and a trench side wall of the adjacent second trenches is generated/amplified.

As an advantageous development of the present invention, each of the gate electrodes located in the second trenches can also comprise a first partial electrode and a second partial electrode, wherein the first partial electrode is located on a side of the associated second partial electrode oriented toward the trench bottom of the relevant second trench, and an intermediate volume between the first partial electrode and the associated second partial electrode is filled with the at least one insulation dielectric. As becomes clear from the following description, the division of the two gate electrodes in the second trenches in each case into the first partial electrode and the associated second partial electrode leads to a lower field load of the at least one insulation dielectric.

In a further advantageous embodiment of the vertical field-effect transistor structure of the present invention, two of the gate electrodes are located in each of the first trenches, wherein the vertical field-effect transistor structure has a metalization on the upper side of the semiconductor body, and a finger structure of the metalization projects into each first trench between the two gate electrodes of the relevant first trench, which are electrically insulated from the adjacent finger structure by means of the at least one insulation dielectric, and wherein each of the finger structures projecting into the first trenches extends through the relevant first trench to the adjacent shielding region. The shielding regions of the embodiment of the vertical field-effect transistor structure described here can thus be electrically contacted by means of the finger structures running through the first trenches.

In addition, two of the gate electrodes can also be located in each of the second trenches, wherein one finger structure of the metalization projects at least into each second trench (between the two gate electrodes of the relevant second trench, which are electrically insulated from the adjacent finger structure by means of the at least one insulation dielectric. In this case, each of the finger structures projecting into the second trenches is preferably electrically insulated from the trench bottom of the relevant second trench by means of the at least one insulation dielectric. The formation of the finger structures projecting into the second trenches is therefore compatible with maintaining an advantageous second average dielectric thickness that is greater than the first average dielectric thickness at least by a factor of 1.2.

In a further advantageous embodiment of the vertical field-effect transistor structure of the present invention, the vertical field-effect transistor structure has a metalization on the upper side of the semiconductor body, and each of the shielding regions is electrically connected to the metalization by means of a doping of the second doping type, which extends through at least one fin located between a first trench and an adjacent second trench. A contacting of the shielding regions of the embodiment of the vertical field-effect transistor structure described here is also possible in this way.

More preferably, the channel zone is doped with ions of the same second doping type as the shielding regions. If the shielding regions are n-doped, then the channel zone is n-doped, whereas if the shielding regions are p-doped, the semiconductor body 10 has a p-doped channel zone. In particular, if the distance between two trenches becomes small, i.e., fins of less than 500 nm, for example, form between the trenches, it may be desirable for the channel zone to be doped with ions of the same first doping type as the drift zone.

In particular, the shielding regions can have a maximum depth, oriented perpendicularly to the surface of the semiconductor body, which is greater than or equal to 50% of a difference between the second trench depth minus the first trench depth. The maximum depth of the shielding regions can be in particular greater than or equal to 75% of the difference between the second trench depth minus the first trench depth, especially greater than or equal to the difference between the second trench depth minus the first trench depth.

The vertical field-effect transistor structure can be, for example, a MOSFET, a TMOSFET and/or a FinMOSFET. The vertical field-effect transistor structure can thus be used in a versatile manner. However, it should be noted that a possible formation of the vertical field-effect transistor structure is not limited to the embodiments described here.

Furthermore, carrying out a corresponding method for producing a vertical field-effect transistor structure of the present invention also provides the advantages explained above. It is expressly pointed out that the method can be further developed in accordance with the embodiments of the vertical field-effect transistor structure of the present invention that are explained above.

### BRIEF DESCRIPTION OF THE DRAWINGS

Further features and advantages of the present invention will be explained in the following with reference to the figures.

FIG. 1 shows a schematic representation of a first embodiment of the vertical field-effect transistor structure, according to the present invention.

FIG. 2 shows a schematic representation of a second embodiment of the vertical field-effect transistor structure, according to the present invention.

FIG. 3 shows a schematic representation of a third embodiment of the vertical field-effect transistor structure, according to the present invention.

FIG. 4 shows a schematic representation of a fourth embodiment of the vertical field-effect transistor structure, according to the present invention.

FIGS. 5A to 5U show schematic representations of intermediate products to explain a first embodiment of the method for producing a vertical field-effect transistor structure, according to the present invention.

FIGS. 6A to 6C show schematic representations of intermediate products to explain a second embodiment of the method for producing a vertical field-effect transistor structure, according to the present invention.

FIGS. 7A to 7D show schematic representations of intermediate products to explain a third embodiment of the method for producing a vertical field-effect transistor structure, according to the present invention.

### DETAILED DESCRIPTION OF EXAMPLE EMBODIMENTS

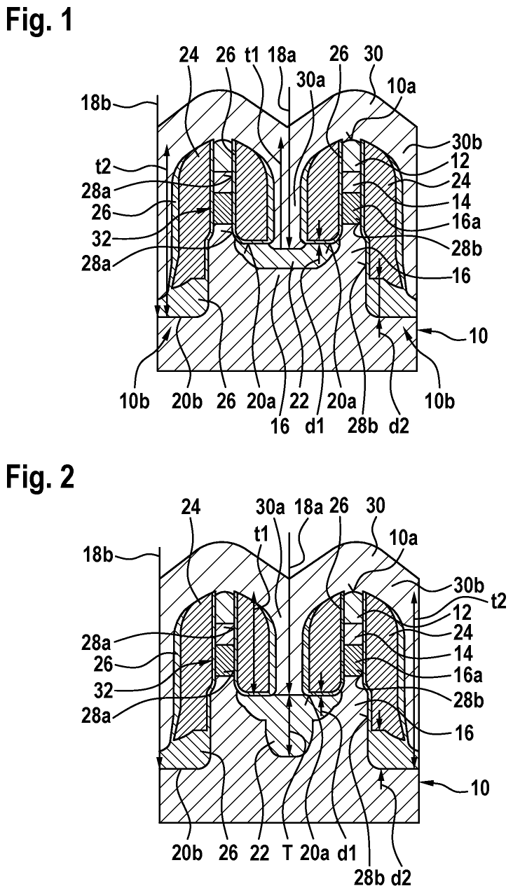

FIG. 1 shows a schematic representation of a first embodiment of the vertical field-effect transistor structure.

The vertical field-effect transistor structure shown schematically in FIG. 1 has a semiconductor body 10 having a surface 10a. The semiconductor body 10 comprises at least one semiconductor material, specifically at least one semiconductor material with a wide band gap, such as silicon carbide (Sic) and/or gallium nitride (GaN). A source zone 12 located adjacent to the surface 10a is formed in the semiconductor body 10. The source zone 12 can in particular be directly adjacent to the surface 10a of the semiconductor body 10. The source zone 12 can, for example, be a (highly) n-doped source zone 12. A channel zone 14 is located on a side of the source zone 12 directed away from the surface 10a. In particular, a p-doped channel zone 14 can be (directly) adjacent to the (highly) n-doped source zone 12. The semiconductor body 10 also has a drift zone 16, which is formed (directly) on a side of the channel zone 14 directed away from the source zone 12. The drift zone 16 has a first doping of a first doping type. If the drift zone 16 is n-doped, a sub-zone 16a of the drift zone 16 can optionally also have a locally increased n-doping (due to an n-spreading implantation).

On the vertical field-effect transistor structure, multiple first trenches 18a and multiple second trenches 18b are also structured through the semiconductor body 10 in such a way that one of the second trenches 18b is located between two adjacent first trenches 18a, and one of the first trenches 18a is located between two adjacent second trenches 18b. This can also be referred to as an “alternating arrangement/design” of the first and second trenches 18a and 18b. Each of the first and second trenches 18a and 18b extends from the surface 10a of the semiconductor body 10 to its trench bottom 20a or 20b located within the drift zone 16. The source zone 12 and the channel zone 14 are thus interrupted by the first and second trenches 18a and 18b, while the first and second trenches 18a and 18b open within a plane of the drift zone 16. The first and second trenches 18a and 18b can also be referred to as trenches. The first trenches 18a have at most a first trench depth t1, while the second trenches 18b have at least a second trench depth t2, which is longer than the first trench depth t1 at least by 50 nm (nanometers). The second trench depth t2 can be longer than the first trench depth t1 in particular by at least 100 nm (nanometers), for example by at least 200 nm (nanometers), in particular by at least 300 nm (nanometers), especially by at least 400 nm (nanometers), optionally also by at least 500 nm (nanometers).

As can also be seen in FIG. 1, the semiconductor body 10 of the vertical field-effect transistor structure has one shielding region 22 adjacent to each trench bottom 20a of the first trenches 18a. Each of the shielding regions 22 adjacent to the trench bottoms 20a of the first trenches 18a is doped with a second doping of a second doping type different from the first doping type of the drift zone 16. This means that, if the drift zone 16 is n-doped, the shielding regions 22 are p-doped, while a semiconductor body 10 formed with a p-doped drift zone 16 has n-doped shielding regions 22. More preferably, the channel zone 14 is doped with ions of the same second doping type as the shielding regions 22. The source zone 12 is doped with ions of the same first doping type as the drift zone 16.

However, each region 10b of the semiconductor body 10 that is adjacent to the trench bottoms 20b of the second trenches 18b is doped exclusively with the first doping of the drift zone 16 and is free from the second doping of the shielding regions 22. In other words, the trench bottoms 20b of the second trenches 18b are free from a shielding region, or shielding regions are “absent” on the trench bottoms 20b of the second trenches 18b.

First and second trenches 18a and 18b are thus formed on the semiconductor body 10 of the vertical field-effect transistor structure with different trench depths t1 and t2, wherein the one shielding region 22 is realized in each case only under the less deep first trenches 18a. Despite the “absence” of shielding regions (directly) on the trench bottoms 20b of the deeper second trenches 18b, the shielding regions 22 adjacent to the trench bottoms 20a of the first trenches 18a form a barrier layer field-effect transistor (JFET, junction-gate field-effect transistor), which, in the event of a short circuit, causes a limitation of the current/short-circuit current flowing through the channel zone 14. As can be seen in FIG. 1, the shielding regions 22 adjacent to the trench bottoms 20a of the less deep first trenches 18a are each located close to a trench side wall of the adjacent deeper second trenches 18b. The advantageous limitation of the short-circuit current is therefore no longer effected by space charge zones of two adjacent shielding regions 22 but by a constriction of the short-circuit current by means of the space charge zone of the relevant shielding region 22 against the opposite trench side wall of the adjacent second trenches 18b.

Therefore, an intermediate distance between two adjacent shielding regions 22 has (substantially) no influence on the limitation of the short-circuit current. Process variations/process variabilities leading to different intermediate distances between two adjacent shielding regions 22 thus make no or hardly any contribution to a deterioration in the desired mode of operation of the vertical field-effect transistor structure. In other words, a lower sensitivity/susceptibility to process variations/process variabilities is achieved in the vertical field-effect transistor structure described here.

At least one gate electrode 24 is formed in each of the first and second trenches 18a and 18b. The at least one gate electrode 24 arranged in each trench 18a or 18b is used to control the adjacent region of the channel zone 14. Each of the gate electrodes 24 is electrically insulated at least from the adjacent trench bottom 20a or 20b and an adjacent trench side wall 28a or 28b of the relevant trench 18a or 18b by means of at least one insulation dielectric 26. The at least one insulation dielectric 26 can comprise at least one electrically insulating material, such as silicon dioxide and/or silicon-rich silicon nitride. In the event of a short circuit, the gate voltage that can be applied by means of the gate electrodes 24 causes an accumulation channel to be formed at the trench side walls, adjacent to the shielding regions 22, of the deeper second trenches 18b, which accumulation channel can only be removed with difficulty by the space charge zone of the adjacent shielding region 22. This also contributes to reducing the sensitivity of the vertical field-effect transistor structure to process variations/process variabilities.

A first average dielectric thickness d1 oriented perpendicularly to the surface 10a of the semiconductor body 10 can be defined for the at least one insulation dielectric 26 (directly) covering at least part of the area of all the trench bottoms 20a of the first trenches 18a. Correspondingly, a second average dielectric thickness d2 oriented perpendicularly to the surface 10a of the semiconductor body 10 can also be defined for the at least one insulation dielectric 26 (directly) covering at least part of the area of all the trench bottoms 20b of the second trenches 18b. The second average dielectric thickness d2 is preferably greater than the first average dielectric thickness d1 at least by a factor of 1.2. The at least one insulation dielectric 26 is thus protected by thickening on the trench bottoms 20b of the deeper second trenches 18b. The formation of shielding regions adjacent to the trench bottoms 20b of the deeper second trenches 18b can thus be omitted without any problem. The second average dielectric thickness d2 can also be greater than the first average dielectric thickness d1 at least by a factor of 1.5, in particular at least by a factor of 2, especially at least by a factor of 3.

Optionally, two of the gate electrodes 24 can be located in each of the first and/or second trenches 18a and 18b. As an optional development, the vertical field-effect transistor structure can also have a metalization 30 on the upper side 10a of the semiconductor body 10, which metalization is designed such that one finger structure 30a or 30b of the metalization 30 projects into each first and/or second trench 18 and 18b between the two gate electrodes 24 of the relevant trench 18a or 18b. The finger structures 30a or 30b projecting into each first and second trench 18 and 18b can be electrically insulated from the adjacent two gate electrodes 24 by means of at least one insulation dielectric 26. Each of the finger structures 30a projecting into the first trenches 18a preferably extends through the relevant first trench 18a into the adjacent shielding region 22, while each of the finger structures 30b projecting into the second trenches 18b is electrically insulated from the trench bottom 20b of the relevant second trench 18b by means of the at least one insulation dielectric 26. The formation of the finger structures 30b projecting into the second trenches 18b is thus compatible with a comparatively large second average dielectric thickness d2.

Optionally, the first and second trenches 18a and 18b can be widened in such a way that the regions of the semiconductor body 10 remaining between two adjacent trenches 18a and 18b are narrowed to form fins/fin structures 32. By means of the formation of the fins 32, it can be ensured that there is sufficient space in the trenches 18a and 18b for the at least one gate electrode 24, the at least one insulation dielectric 26 and possibly also for the inwardly protruding finger structure 30a or 30b. In this way, a low pitch measure is also made possible. Since no space for a connection is required in the deeper second trenches 18b, the second trenches 18b can optionally also be narrower than the first trenches 18a, in order to save pitch.

FIG. 2 shows a schematic representation of a second embodiment of the vertical field-effect transistor structure.

As can be seen from the vertical field-effect transistor structure of FIG. 2, the shielding regions 22 can be formed with a maximum depth T, oriented perpendicularly to the surface 10a of the semiconductor body 10, which is greater than or equal to 50% of a difference between the second trench depth t2 minus the first trench depth t1. The shielding regions 22 can therefore also project deeper than the second trenches 18b into the semiconductor body 10.

With respect to further features of the vertical field-effect transistor structure of FIG. 2 and their advantages, reference is made to the above description of FIG. 1.

FIG. 3 shows a schematic representation of a third embodiment of the vertical field-effect transistor structure.

As the only difference from the embodiment of FIG. 1, in the vertical field-effect transistor structure of FIG. 3, each of the gate electrodes 24 located in the second trenches 18b comprises one first partial electrode 24a and one second partial electrode 24b. The first partial electrode 24a is arranged on a side of the associated second partial electrode 24b oriented toward the trench bottom 20b of the relevant second trench 18b, wherein an intermediate volume between the first partial electrode 24a and the associated second partial electrode 24b is filled with the at least one insulation dielectric 26. The first partial electrode 24a is thus (artificially) held at the low potential of the source zone 12. This causes a lower field load of the at least one insulation dielectric 26 and an amplification of the shielding effect with respect to a short circuit. Although this is not shown in FIG. 3, the relevant gate electrode 24 can comprise one first partial electrode 24a and one second partial electrode 24b even when exactly one gate electrode 24 is arranged in each of the second trenches 18b.

With respect to further features of the vertical field-effect transistor structure of FIG. 3 and their advantages, reference is made to the description of FIG. 1.

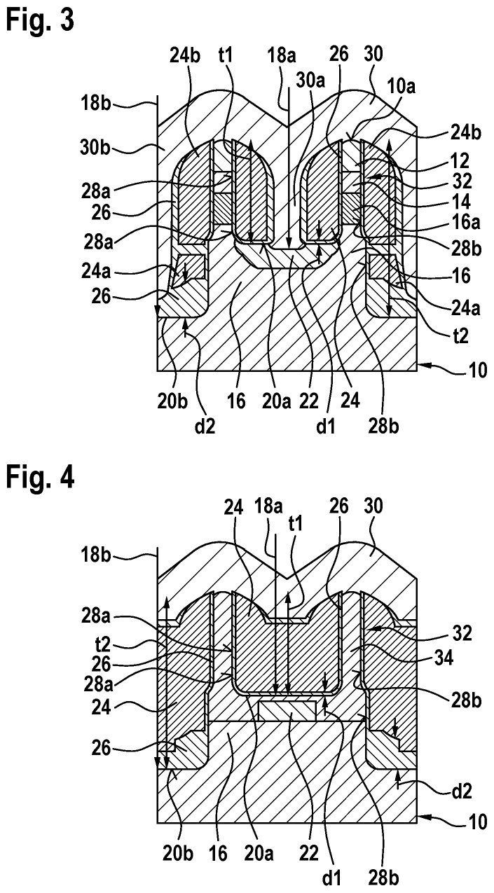

FIG. 4 shows a schematic representation of a fourth embodiment of the vertical field-effect transistor structure.

In contrast to the embodiments of FIGS. 1 to 3 described above, the vertical field-effect transistor structure of FIG. 4 has a metalization 30 without finger structures on the upper side 10a of its semiconductor body 10. In the vertical field-effect transistor structure of FIG. 4, each of the shielding regions 22 is therefore electrically connected to the metalization 30 by means of a doping 34 of the second doping type, which extends through at least one fin 32 located between the relevant first trench 18a and the relevant adjacent second trench 18b. This takes place at least at one location within the cell field or at periodic intervals along the trenches 18a and 18b. Thus, locations with source/channel/drift doping within the mesas/fins 32 alternate with the deep doping 34 of the second doping type. The doping 34 of the second doping type can be, for example, a p-doping 34.

With respect to further features of the vertical field-effect transistor structure of FIG. 4 and their advantages, reference is made to the description of FIG. 1.

All the vertical field-effect transistor structures described above can advantageously be used as a MOSFET (metal oxide semiconductor field-effect transistor), in particular as a power MOSFET. Such a MOSFET can also be referred to as a MOSFET with a vertical channel region (TMOSFET, trench metal oxide semiconductor field-effect transistor) or as a MOSFET with fins (FinMOSFET, fin metal oxide semiconductor field-effect transistor). For each of the vertical field-effect transistor structures explained above, a switch-on resistance, a threshold voltage, a short-circuit resistance, an oxide load, and a breakdown voltage can be optimized by suitably selecting their geometry, epitaxy doping, channel doping and screening doping.

Each of the vertical field-effect transistor structures explained above is suitable for a plurality of uses in power electronics. For example, such a vertical field-effect transistor structure can be used in a converter, especially in a DC/DC converter, an inverter, a vehicle charging device (automotive charger) or in an electric powertrain of a vehicle.

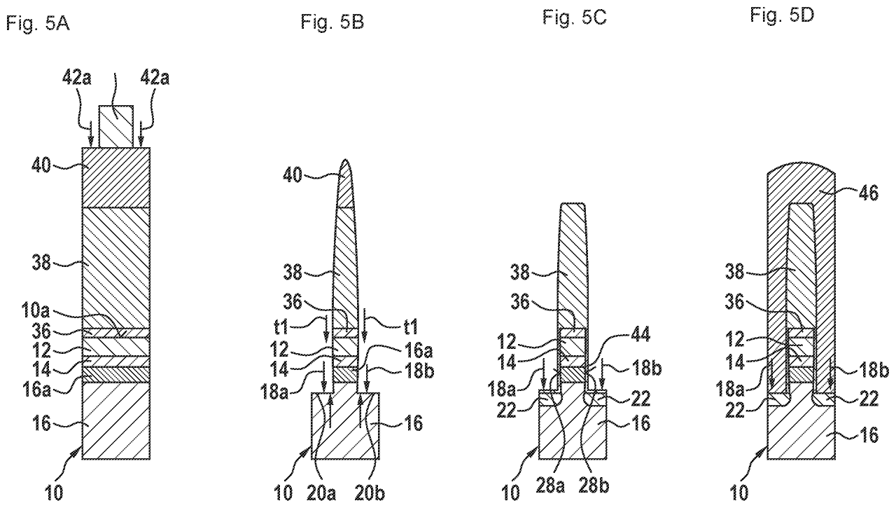

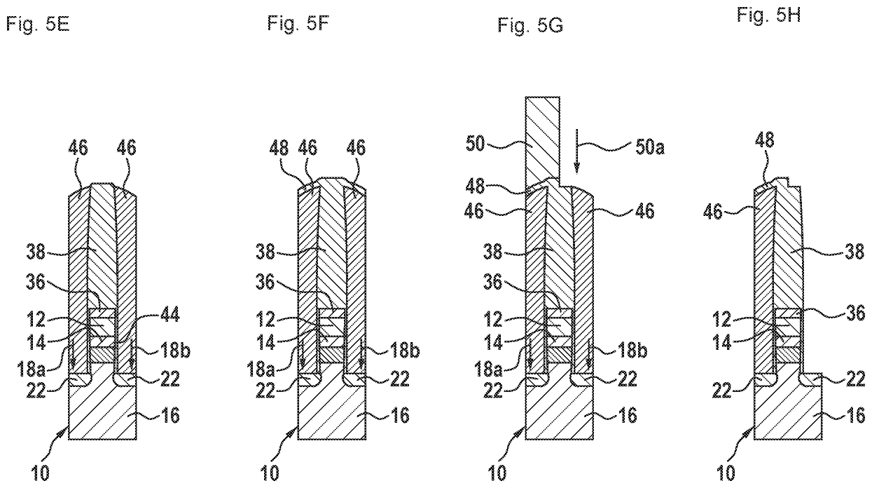

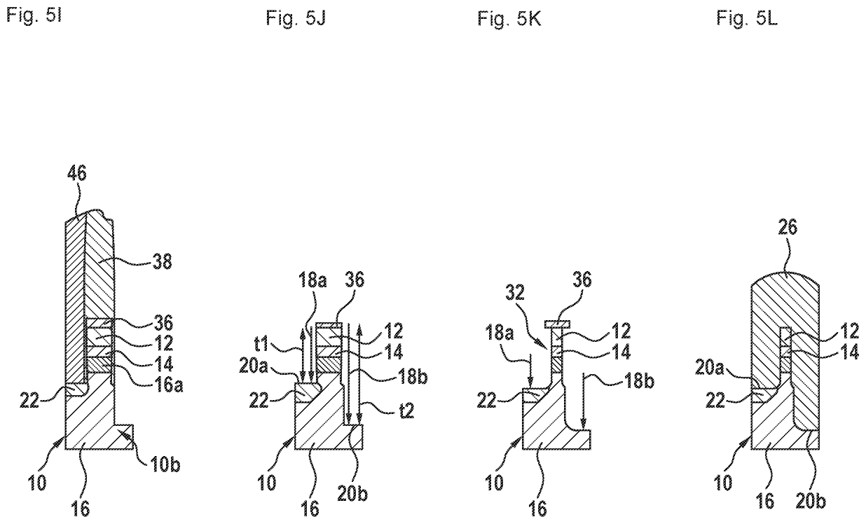

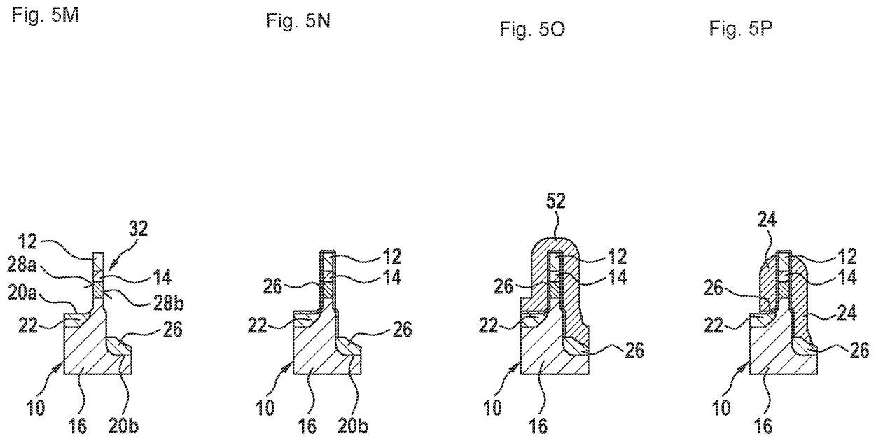

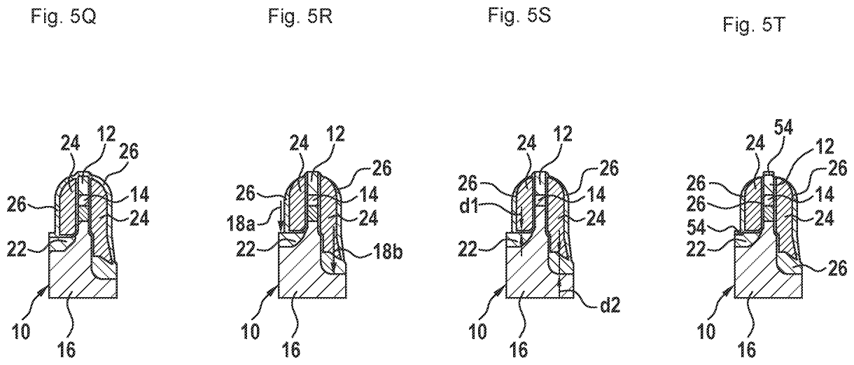

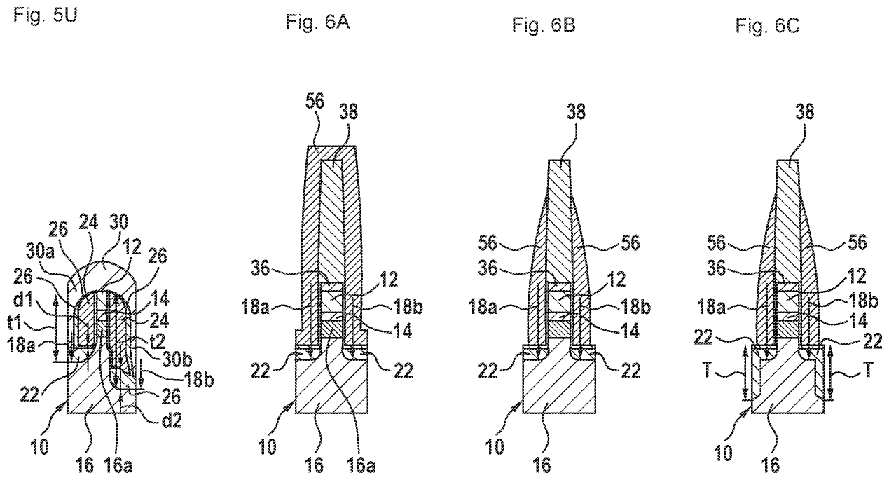

FIGS. 5A to 5U show schematic representations of intermediate products to explain a first embodiment of the method for producing a vertical field-effect transistor structure.

In the method described here, a source zone 12, a channel zone 14 and a drift zone 16 are first formed in a semiconductor body 10. The source zone 12 is formed adjacent to a surface 10a of the semiconductor body 10, the channel zone 14 is formed on a side of the source zone 12 directed away from the surface 10a, and the drift zone 16 is formed on a side of the channel zone 14 directed away from the source zone 12 in the semiconductor body 10. The drift zone 16 is doped with a first doping of a first doping type. Preferably, the source zone 12 is formed by means of a (strong) n-implantation, and the channel zone 14 is formed by means of a p-implantation. Optionally, an n-spreading implantation can also be carried out in order to locally increase the concentration of the n-doping in a sub-zone 16a of the n-doped drift zone 16.

Subsequently, in the embodiment described here, a nitride mask 36 is first deposited on the surface 10a of the semiconductor body 10, and then an oxide mask 38 is deposited on a side of the nitride mask 36 directed away from the semiconductor body 10. A side of the oxide mask 38 directed away from the nitride mask 36 can then be covered with polysilicon 40. An etch mask 42 (consisting of a photosensitive lacquer, for example) can then be formed on a side of the polysilicon 40 directed away from the oxide mask 38. By means of a structuring of continuous cut-outs 42a through the etch mask 42, the positions of later first trenches 18a and second trenches 18b on the semiconductor body 10 can be defined. The intermediate product obtained in this way is shown in FIG. 5A.

In a method step shown schematically by means of FIG. 5B, multiple first trenches 18a and multiple second trenches 18b are structured into the semiconductor body 10 by the masks 36 and 38 in such a way that one of the second trenches 18b is located between two adjacent first trenches 18a, and one of the first trenches 18a is located between two adjacent second trenches 18b. The etching step for the common structuring of the first and second trenches 18a and 18b can be carried out until each of the first and second trenches 18a and 18b extends from the surface 10a of the semiconductor body 10 to its trench bottom 20a or 20b located within the drift zone. After the etching step has been concluded, both the first trenches 18a and the second trenches 18b have at most a first trench depth t1. The first trench depth t1 can, for example, be between 1 μm (micrometers) to 2 μm (micrometers). A maximum width of the first and second trenches 18a and 18b oriented parallel to the surface 10a of the semiconductor body 10 can be, for example, greater than or equal to 200 nm (nanometers) and less than or equal to 1000 nm (nanometers). A later intermediate distance between shielding regions 22 (explained below) under the first trenches 18a and an adjacent trench side walls of the subsequently deepened second trenches 18b is defined in a self-adjusted manner by the intermediate trench distances maintained during the etching of the trenches 18a and 18b, and by a trench widening explained below.

Optionally, after the etching step, a diffusion oxide deposition is carried out in order to cover the trench bottoms 20a and 20b and trench walls 28a and 28b of the first and second trenches 18a and 18b with a diffusion oxide 44. In a further method step, one shielding region 22 is formed adjacent to each trench bottom 20a and 20b of the first and second trenches 18a and 18b, which shielding region is doped with a second doping of a second doping type different from the first doping type of the drift zone 16. FIG. 5C shows the obtained intermediate product before removal of the diffusion oxide 44 from the trench bottoms 20a and 20b by means of anisotropic diffusion oxide etching.

In FIG. 5D, the intermediate product is schematically shown after a deposition of polysilicon 46 for filling the first and second trenches 18a and 18b. As can be seen in FIG. 5E, the polysilicon 46 protruding from the trenches 18a and 18b can subsequently be removed by means of a polysilicon etching-back step. Subsequently, as shown in FIG. 5F, a silicon dioxide layer 48 is formed on the polysilicon 46 remaining in the trenches 18a and 18b. This can be done, for example, by means of an oxide deposition.

In the method described here, after the shielding regions 22 have been formed, while the first trenches 18a are structured into the semiconductor body 10 at most with the first trench depth t1, the second trenches 18b are deepened into the semiconductor body 10 to at least a second trench depth t2. Therefore, a further etch mask 50 (in particular consisting of a photosensitive lacquer) is applied on the silicon dioxide layer 48 and structured by the formation of continuous cut-outs 50a in such a way that, after an oxide etching step, the polysilicon 46 with which the second trenches 18b are filled is exposed (see FIG. 5G). Process variabilities occurring during the formation of the etching mask 50 have no influence on the minimum achievable pitch, or the achievable optimum of switch-on resistance and short-circuit current, since the process variability is generally smaller than a trench intermediate width between two adjacent trenches 18a and 18b.

FIGS. 5H and 5I show the selective polysilicon etching subsequently executed to deepen the second trenches 18b into the semiconductor body 10, which is carried out until the second trenches have at least the desired second trench depth t2, which is longer than the first trench depth t1 at least by 50 nm (nanometers). The second trench depth t2 can in particular be longer than the first trench depth t1 by at least 100 nm (nanometers), for example by at least 200 nm (nanometers), in particular by at least 300 nm (nanometers), especially by at least 400 nm (nanometers), optionally also by at least 500 nm (nanometers). While the shielding regions 22 adjacent to each trench bottom 20a of the first trenches 18a remain (substantially) unaffected by the selective polysilicon and SiC etching shown by means of FIGS. 5H and 5I, the trench bottoms 20b of the second trenches 18b are deepened into the semiconductor body 10 in such a way that each region 10b of the semiconductor body 10 that is adjacent to the deepened trench bottoms 20b of the second trenches 18b has exclusively the first doping of the drift zone 16 and is free from the second doping of the shielding regions 22. The formation/maintenance of the shielding regions 22 only adjacent to the trench bottoms 20a of the first trenches 18a serves to limit the current flow at the point between a shielding region 22 and an adjacent trench side wall of the deeper second trench 18b, or an electrical field below a critical field strength in the case of blocking. FIG. 5J shows the intermediate product after removal of (residues) of the oxide mask 38 and (residues) of the polysilicon 46.

As shown schematically in FIG. 5K, the first and second trenches 18a and 18b are then preferably widened by means of multiple cyclic oxidation and oxide etching steps in such a way that the regions/mesas of the semiconductor body 10 remaining between two adjacent trenches 18a and 18b are narrowed to form fins/fin structures 32. The nitride mask 36 prevents oxidation at the peaks of the fins 32 and thus contributes to optimizing the fin shape. However, the use of the nitride mask 36 is optional.

In the method described here, at least one gate electrode 24 is also formed in each of the first and second trenches 18a and 18b, wherein each of the gate electrodes 24 is electrically insulated at least from the adjacent trench bottom 20a or 20b and the adjacent trench side wall 28a or 28b of the relevant trench 18a or 18b by means of at least one insulation dielectric 26. For this purpose, the at least one insulation dielectric 26 is first deposited at least partially in the first and second trenches 18a and 18b. At least part of the area of the trench bottoms 20a of the first trenches 18a and the trench bottoms 20b of the second trenches 18b is covered with the at least one insulation dielectric 26 in such a way that a first average dielectric thickness d1 oriented perpendicularly to the surface 10a of the semiconductor body 10 can be defined for the at least one insulation dielectric 26 (directly) covering all the trench bottoms 20a of the first trenches 18a, and a second average dielectric thickness d2 oriented perpendicularly to the surface 10a of the semiconductor body 10 can be defined for the at least one insulation dielectric 26 (directly) covering all the trench bottoms 20b of the second trenches 18b. Specifically, in the embodiment of the method described here, the second average dielectric thickness d2 is greater than the first average dielectric thickness d1 at least by a factor of 1.2 (see FIG. 5R). The second average dielectric thickness d2 can also be greater than the first average dielectric thickness d1 at least by a factor of 1.5, in particular at least by a factor of 2, especially at least by a factor of 3. Therefore, in the method described here, the first and second trenches 18a and 18b are first completely filled with silicon dioxide as the at least one insulation dielectric 26 (see FIG. 5L). The silicon dioxide is then etched back until the first trenches 18a are free from the silicon dioxide. As shown schematically in FIG. 5M, in this case a residue of the silicon dioxide remains on the trench bottoms 20b of the second trenches 18b. FIG. 5N shows the intermediate product after an additional silicon dioxide layer is formed as the at least one insulation dielectric 26, so that the trench bottoms 20a and trench walls 28a of the first trenches 18a are also covered (substantially) completely with silicon dioxide 26.

In the method described here, two of the gate electrodes 24 are also formed in each of the first and second trenches 18a and 18b. For this purpose, the silicon dioxide 26 covering the trench bottoms 20a and 20b and trench side walls 28a and 28b of the first and second trenches 18a and 18b is covered with the polysilicon layer 52, as shown in FIG. 5O. By means of anisotropic selective polysilicon etching, the central regions of the trench bottoms 20a and 20b can subsequently be exposed by the polysilicon layer 52. In addition, the regions of the polysilicon layer 52 previously protruding out of the trenches 18a and 18b are also etched back to such an extent that only the polysilicon of the polysilicon layer 52 that is required for forming the gate electrodes 24 remains in the trenches 18a and 18b (see FIG. 5P).

In order to electrically insulate the gate electrodes 24 from a later finger structure 30a or 30b, silicon dioxide 26 is subsequently deposited again as the at least one insulation dielectric 26, as can be seen from FIG. 5Q. To enable a later electrical contacting of the shielding regions 22 and the source zone 12, the silicon dioxide is then removed from the central regions of the trench bottoms 20a of the first trenches 18a and on the fin peaks by means of a short oxide etching step. In this case, the short oxide etching step is terminated early so that it only brings about an (insignificant) dilution of the silicon dioxide 26 at the central regions of the trench bottoms 20b of the second trenches 18b (see FIG. 5R). By means of subsequent reoxidation, the silicon dioxide layer 26 electrically insulating the gate electrodes 24 from the later adjacent finger structure can be slightly thickened again. The intermediate result is shown in FIG. 5S.

FIG. 5T shows the intermediate product after deposition of a nickel layer and subsequent silicidation, in which nickel can react with SiC to form nickel silicide only on the exposed central regions of the trench bottoms 20a of the first trenches 18a and on the protruding peaks of the fins 32. Subsequently, the remaining nickel is etched, so that only the nickel silicide regions 54 remain. A metalization 30 with a finger structure 30a and 30b projecting into each of the first and second trenches 18a and 18b is then formed on the upper side 10a of the semiconductor body 10. Each of the finger structures 30a and 30b is formed between the two gate electrodes 24 of the relevant trench 18a or 18b, which are electrically insulated from the adjacent finger structure 30a or 30b by means of the at least one insulation dielectric 26. In an alternative embodiment, the shielding regions 22 can also be contacted along the first trenches by forming a correspondingly deep p-implantation in the fins 32.

In comparison with the related art, the product shown in FIG. 5U thus has different trench depths t1 and t2 of its first and second trenches 18a and 18b and a “thickened” trench bottom oxide on the trench bottoms 20b of the deeper second trenches 18b.

FIGS. 6A to 6C show schematic representations of intermediate products to explain a second embodiment of the method for producing a vertical field-effect transistor structure.

The method shown by means of FIGS. 6A to 6C is a development of the embodiment explained above.

For this purpose, according to the method steps shown by means of FIGS. 5A to 5C, a polysilicon layer 56 is deposited in and on the trenches 18a and 18b, the layer thickness of which is so thin that the trenches 18a and 18b are only partially filled (see FIG. 6A). The central regions of the trench bottoms 20a and 20b are then exposed by means of anisotropic, selective polysilicon etching. Optionally, the regions of the polysilicon layer 56 previously protruding out of the trenches 18a and 18b can also be removed. The intermediate product is shown in FIG. 6B.

As can be seen from FIG. 6C, a maximum depth T of the shielding regions 22 perpendicular to the surface 10a of the semiconductor body 10 can then be increased by means of another doping with the second doping of the second doping type (similar to the doping previously carried out to form the shielding regions 22). If this is done after each second trench, following steps 5d to 5h, has previously been covered, the distance of this deeper implantation from the side wall of the subsequently deepened second trench can thus be set independently of the original width of the shielding regions 22. If only the first trenches are implanted in this way, the implantation depth T can also extend deeper than the depth of the second trenches, since no deep regions that are doped with the second doping type have to be removed during the etching of the second trenches.

With regard to further method steps of the method of FIGS. 6A to 6C, reference is made to the embodiment explained above.

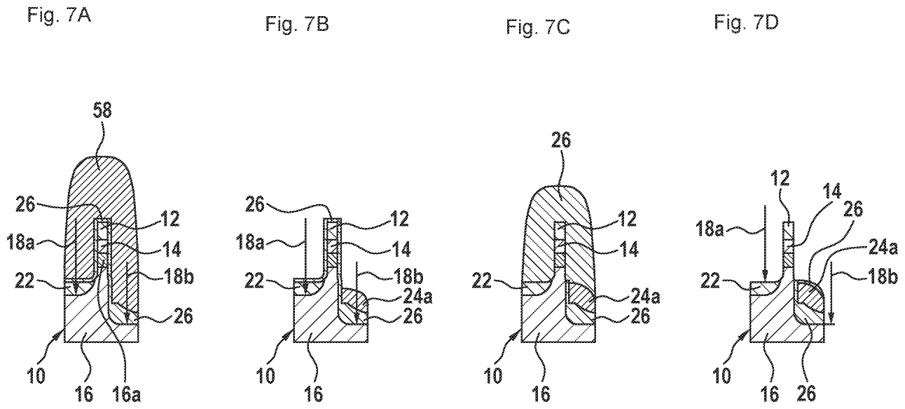

FIGS. 7A to 7D show schematic representations of intermediate products to explain a third embodiment of the method for producing a vertical field-effect transistor structure.

As a development of the embodiment of FIGS. 5A to 5U, in the method of FIGS. 7A to 7D, each of the gate electrodes 24 located in the second trenches 18b is formed as a first partial electrode 24a and a second partial electrode 24. The first partial electrode 24a is arranged on a side of the associated second partial electrode 24b oriented toward the trench bottom 20b of the relevant second trench 18b, while an intermediate volume between the first partial electrode 24a and the associated second partial electrode 24b is filled with the at least one insulation dielectric 26.

For this purpose, after the method steps shown in FIGS. 5A to 5N are carried out, a polysilicon deposition is carried out in order to fill the trenches 18a and 18b with polysilicon 58 (preferably completely) (see FIG. 7A). The polysilicon 58 is then etched back until the first trenches 18a are (almost) free from the polysilicon 58. As shown schematically in FIG. 7B, in this case a residue of the polysilicon 58 remains on the trench bottoms 20b of the second trenches 18b, which forms the relevant first partial electrode 24a. Thereafter, silicon dioxide is again deposited as the at least one insulation dielectric 26 until the first and second trenches 18a and 18b are completely filled (see FIG. 7C). The silicon dioxide is then etched back until the first trenches 18a are (almost) free from the silicon dioxide. A residue of the silicon dioxide covering the relevant first partial electrode 24a thus still remains in the second trenches 18b. FIG. 7D shows the intermediate product.

With regard to further method steps of the method of FIGS. 7A to 7D, reference is made to the embodiment explained above.

1-13. (canceled)

14. A vertical field-effect transistor structure, comprising:
a semiconductor body having a surface, wherein a source zone located adjacent to the surface, a channel zone located on a side of the source zone directed away from the surface, and a drift zone located on a side of the channel zone directed away from the source zone, are formed in the semiconductor body, and the drift zone has a first doping of a first doping type;
multiple first trenches and multiple second trenches, wherein one of the second trenches is located between two adjacent first trenches, and one of the first trenches is located between two adjacent second trenches, and each of the first and second trenches extends from the surface of the semiconductor body to its trench bottom located within the drift zone, and wherein the first trenches have at most a first trench depth, and the second trenches have at least a second trench depth, and the second trench depth is longer than the first trench depth at least by 50 nm;
a shielding region adjacent to each of the trench bottoms of the first trenches, the shielding region having a second doping of a second doping type different from the first doping type of the drift zone; and
at least one gate electrode in each of the first and second trenches, wherein each of the gate electrodes is electrically insulated at least from an adjacent trench bottom and an adjacent trench side wall of a relevant trench by at least one insulation dielectric;
wherein each region of the semiconductor body that is adjacent to the trench bottoms of the second trenches has exclusively the first doping of the drift zone and is free from the second doping.

15. The vertical field-effect transistor structure according to claim 14, wherein a first average dielectric thickness oriented perpendicularly to the surface of the semiconductor body is defined for the at least one insulation dielectric covering at least part of an area of all of the trench bottoms of the first trenches, and a second average dielectric thickness oriented perpendicularly to the surface of the semiconductor body is defined for the at least one insulation dielectric covering at least part of the area of all of the trench bottoms of the second trenches, wherein the second average dielectric thickness is greater than the first average dielectric thickness at least by a factor of 1.2.

16. The vertical field-effect transistor structure according to claim 14, wherein each of the gate electrodes located in the second trenches includes a first partial electrode and an associated second partial electrode, and wherein the first partial electrode is located on a side of the associated second partial electrode oriented toward the trench bottom of the second trench, and an intermediate volume between the first partial electrode and the associated second partial electrode is filled with the at least one insulation dielectric.

17. The vertical field-effect transistor structure according to claim 14, wherein two of the gate electrodes are located in each first trench of the first trenches, wherein the vertical field-effect transistor structure has a metalization on an upper side of the semiconductor body, and a finger structure of the metalization projects at least into each first trench between the two gate electrodes of the first trench, which are electrically insulated from an adjacent finger structure by the at least one insulation dielectric, and wherein each of the finger structures projecting into the first trenches extends through the first trench to the adjacent shielding region.

18. The vertical field-effect transistor structure according to claim 17, wherein two of the gate electrodes are located in each second trench of the second trenches, wherein a finger structure of the metalization projects at least into each second trench between the two gate electrodes of the second trench, which are electrically insulated from the adjacent finger structure by means the at least one insulation dielectric, and wherein each of the finger structures projecting into the second trenches is electrically insulated from the trench bottom of the second trench by the at least one insulation dielectric.

19. The vertical field-effect transistor structure according to claim 14, wherein the vertical field-effect transistor structure has a metalization on an upper side of the semiconductor body, and each of the shielding regions is electrically connected to the metalization by a doping of the second doping type, which extends through at least one fin located between a first trench of the first trenches and an adjacent second trench of the second trenches.

20. The vertical field-effect transistor structure according to claim 14, wherein the channel zone is doped with ions of the same second doping type as the shielding regions.

21. The vertical field-effect transistor structure according to claim 14, wherein the shielding regions have a maximum depth, oriented perpendicularly to the surface of the semiconductor body, which is greater than or equal to 50% of a difference between the second trench depth minus the first trench depth.

22. A method for producing a vertical field-effect transistor structure, comprising the following steps:
forming, in a semiconductor body, a source zone located adjacent to a surface of the semiconductor body, a channel zone located on a side of the source zone directed away from the surface, and a drift zone located on a side of the channel zone directed away from the source zone, wherein the drift zone is doped with a first doping of a first doping type;
structuring multiple first trenches and multiple second trenches in such a way that one of the second trenches lies between two adjacent first trenches, and one of the first trenches lies between two adjacent second trenches, and each of the first and second trenches extends from the surface of the semiconductor body to its trench bottom located within the drift zone;
forming a shielding region adjacent to at least each trench bottom of the first trenches, the shielding region being doped with a second doping of a second doping type different from the first doping type of the drift zone; and
forming at least one gate electrode in each of the first and second trenches, wherein each of the gate electrodes is electrically insulated at least from an adjacent trench bottom and an adjacent trench side wall of a relevant trench by at least one insulation dielectric;
while the first trenches are structured into the semiconductor body at most with a first trench depth, after the shielding regions have been formed, the second trenches are deepened into the semiconductor body to at least a second trench depth which is longer than the first trench depth at least by 50 nm, so that each region of the semiconductor body that is adjacent to the deepened trench bottoms of the second trenches has exclusively the first doping of the drift zone and is free from the second doping.

23. The method according to claim 22, wherein at least part of an area of the trench bottoms of the first trenches and the trench bottoms of the second trenches is covered with the at least one insulation dielectric in such a way that a first average dielectric thickness oriented perpendicularly to the surface of the semiconductor body is defined for the at least one insulation dielectric covering all of the trench bottoms of the first trenches, and a second average dielectric thickness oriented perpendicularly to the surface of the semiconductor body is defined for the at least one insulation dielectric covering all of the trench bottoms of the second trenches, wherein the second average dielectric thickness is greater than the first average dielectric thickness at least by a factor of 1.2.

24. The method according to claim 22, wherein two of the gate electrodes are formed in each first trench of the first trenches, and wherein a metalization having a finger structure projecting into each of the first trenches is formed on an upper side of the semiconductor body, and wherein each of the finger structures is formed between the two gate electrodes of the first trench, which are electrically insulated from an adjacent finger structure by the at least one insulation dielectric.

25. The method according to claim 22, wherein each of the gate electrodes located in each second trench of the second trenches is formed as a first partial electrode and an associated second partial electrode, wherein the first partial electrode is arranged on a side of the associated second partial electrode oriented toward the trench bottom of the second trench, and an intermediate volume between the first partial electrode and the associated second partial electrode is filled with the at least one insulation dielectric.

26. The method according to claim 22, wherein, after the shielding regions have been formed, a polysilicon layer is deposited in and on the first and/or second trenches, and then central regions of the trench bottoms of the first and/or second trenches are exposed, and then a maximum depth of the shielding regions perpendicular to the surface of the semiconductor body is increased by another doping with the second doping of the second doping type.
